(19) United States
(12) Patent Application Publication
(10) Pub. No.: US 2020/0243461 A1
(43) Pub. Date: Jul. 30, 2020

(54) SEMICONDUCTOR PACKAGE AND MANUFACTURING METHOD THEREOF

(71) Applicant: Powertech Technology Inc., Hsinchu County (TW)

(72) Inventors: Chia-Wei Chiang, Hsinchu County (TW); Li-Chih Fang, Hsinchu County (TW); Wen-Jeng Fan, Hsinchu County (TW)

(73) Assignee: Powertech Technology Inc., Hsinchu County (TW)

(21) Appl. No.: 16/261,561

(22) Filed: Jan. 30, 2019

(51) Int. Cl. H01L 23/00; H01L 23/31; H01L 23/538; H01L 25/10; H01L 25/00; H01L 21/48; H01L 21/56

(52) U.S. Cl. CPC H01L 23/562; H01L 2225/1035; H01L 23/3135; H01L 23/5383; H01L 23/5386; H01L 23/5389; H01L 24/20; H01L 24/19; H01L 25/105; H01L 25/50; H01L 21/4857; H01L 21/4853; H01L 21/568; H01L 21/565; H01L 2224/214; H01L 2924/3511; H01L 2225/1058; H01L 23/3128

(57) ABSTRACT

A semiconductor package and a manufacturing method thereof are provided. The semiconductor package includes a bumpless die including a plurality of conductive pads, a conductive connector disposed aside the bumpless die and electrically coupled to the bumpless die, an insulating encapsulation encapsulating the bumpless die and the conductive connector, a circuit layer electrically connected to the bumpless die and the conductive connector, and a front side redistribution layer disposed on the circuit layer and including a finer line and spacing routing than the circuit layer. The circuit layer includes a conductive pattern disposed on the insulating encapsulation and extending along a thickness direction of the bumpless die to be connected to the conductive pads of the bumpless die, and a dielectric pattern disposed on the insulating encapsulation and laterally covering the conductive pattern.

### BACKGROUND OF THE INVENTION

### Field of Invention

The present invention generally relates to a package structure and a manufacturing method thereof, and more particularly, to a semiconductor package including a bumpless die and a manufacturing method thereof.

### Description of Related Art

In recently years, electronic apparatus are more important for human's life. In order for electronic apparatus design to achieve being light, slim, short, and small, semiconductor packaging technology has kept progressing, in attempt to develop products that are smaller in volume, lighter in weight, higher in integration, and more competitive in market. Since the semiconductor packaging technique is highly influenced by the development of integrated circuits; therefore, as the size of electronics has become demanding, so does the package technique. As such, how to achieve a semiconductor package with better electrical performance while maintaining the process simplicity and miniaturization of structure has become a challenge to researchers in the field.

### SUMMARY OF THE INVENTION

The disclosure provides a semiconductor package and a manufacturing method thereof, which provides improvement in electrical performance and greater manufacturability.

The disclosure provides a semiconductor package. The semiconductor package includes a bumpless die including a plurality of conductive pads, a conductive connector disposed aside the bumpless die and electrically coupled to the bumpless die, an insulating encapsulation encapsulating the bumpless die and the conductive connector, a circuit layer electrically connected to the bumpless die and the conductive connector, and a front side redistribution layer disposed on the circuit layer and including a finer line and spacing routing than the circuit layer. The circuit layer includes a conductive pattern disposed on the insulating encapsulation and extending along a thickness direction of the bumpless die to be connected to the conductive pads of the bumpless die, and a dielectric pattern disposed on the insulating encapsulation and laterally covering the conductive pattern.

The disclosure provides a manufacturing method of a semiconductor package. The manufacturing method includes at least the following steps. An insulating encapsulation is formed to encapsulate a bumpless die and a conductive connector, where the bumpless die includes a plurality of conductive pads unmasked by the insulating encapsulation. A dielectric pattern is formed on the insulating encapsulation, where the dielectric pattern includes a plurality of openings exposing the conductive pads of the bumpless die and at least a portion of the conductive connector. A conductive material is formed in the openings of the dielectric pattern to form a conductive pattern, where the conductive pattern is formed on the conductive pads of the bumpless die and laterally extend to cover the insulating encapsulation. A front side redistribution layer is formed on the dielectric pattern and the conductive pattern, where the front side redistribution layer is electrically coupled to the bumpless die through the conductive pattern.

Based on the above, since the semiconductor package includes the conductive pattern of the circuit layer serving as pseudo-bump to connect the conductive pads of the bumpless die, and also the conductive pattern reroutes the electrical signal of the bumpless die to expand wider than the size of the bumpless die. Moreover, the conductive pattern may be connected to the conductive connectors such that the better electrical performance of the semiconductor package may be achieved while maintaining the process simplicity.

To make the above features and advantages of the present disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A to FIG. 1F are schematic cross-sectional views illustrating a manufacturing method of a semiconductor package according to an embodiment of the disclosure.

FIG. 2A to FIG. 2D are schematic cross-sectional views illustrating a manufacturing method of a semiconductor package according to an embodiment of the disclosure.

FIG. 3A to FIG. 3F are schematic cross-sectional views illustrating a manufacturing method of a semiconductor package according to an embodiment of the disclosure.

FIG. 4A to FIG. 4D are schematic cross-sectional views illustrating a manufacturing method of a semiconductor package according to an embodiment of the disclosure.

FIG. 5A to FIG. 5D are schematic cross-sectional views illustrating a manufacturing method of a semiconductor package according to an embodiment of the disclosure.

FIG. 6 is a schematic cross-sectional view illustrating an application of a semiconductor package according to an embodiment of the disclosure.

### DESCRIPTION OF EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

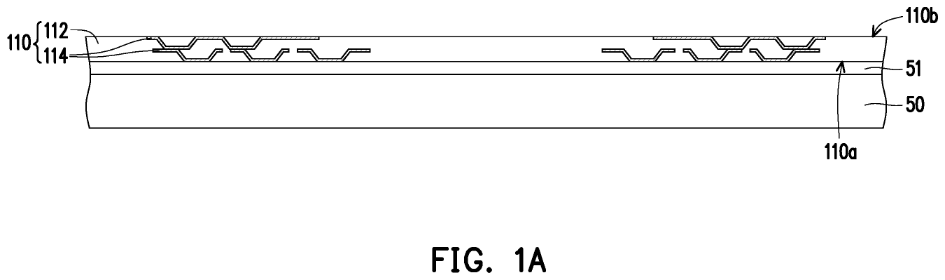

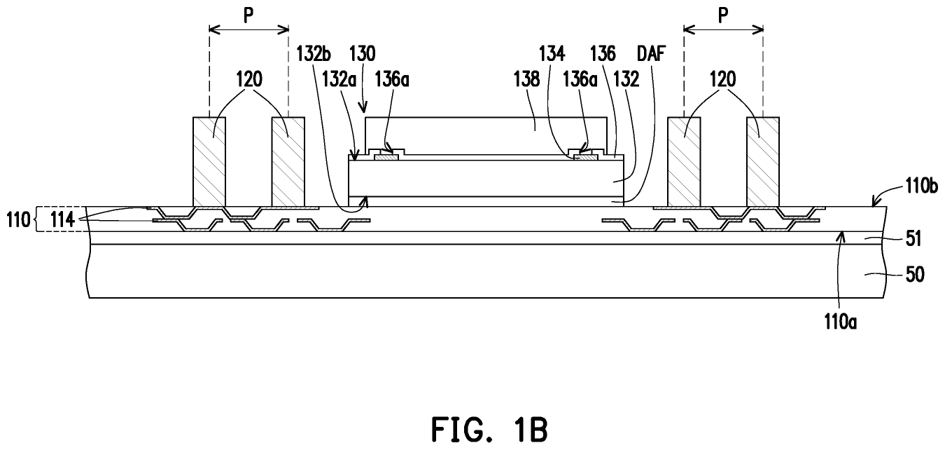

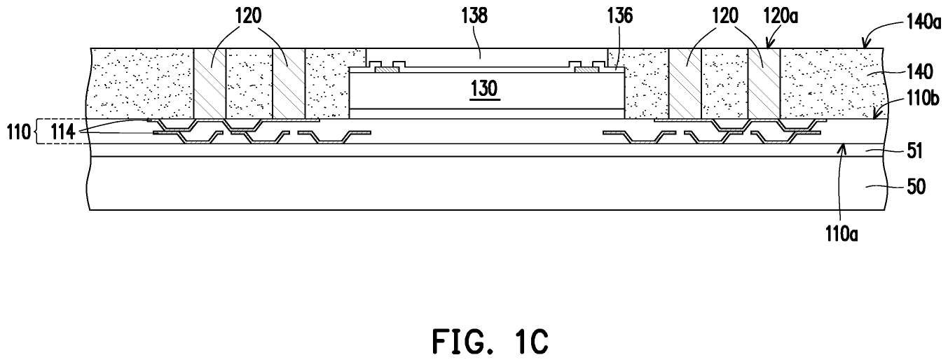

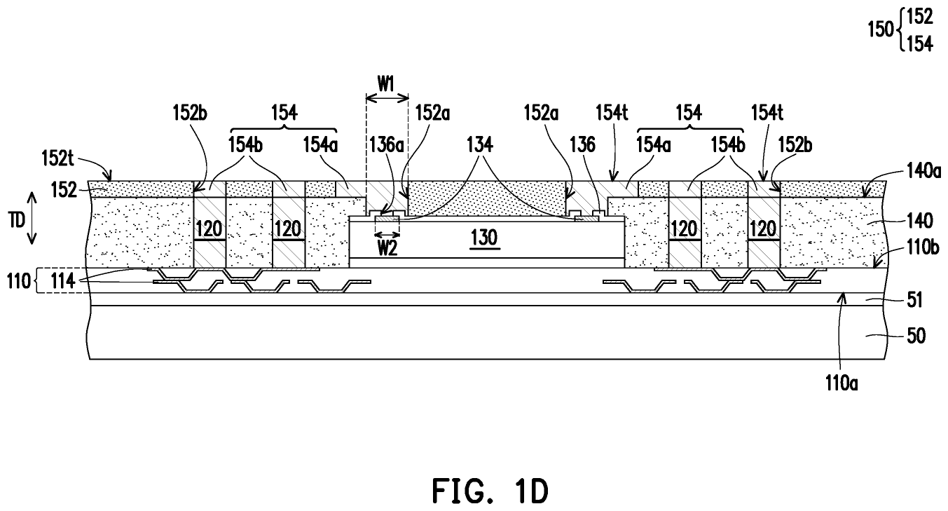

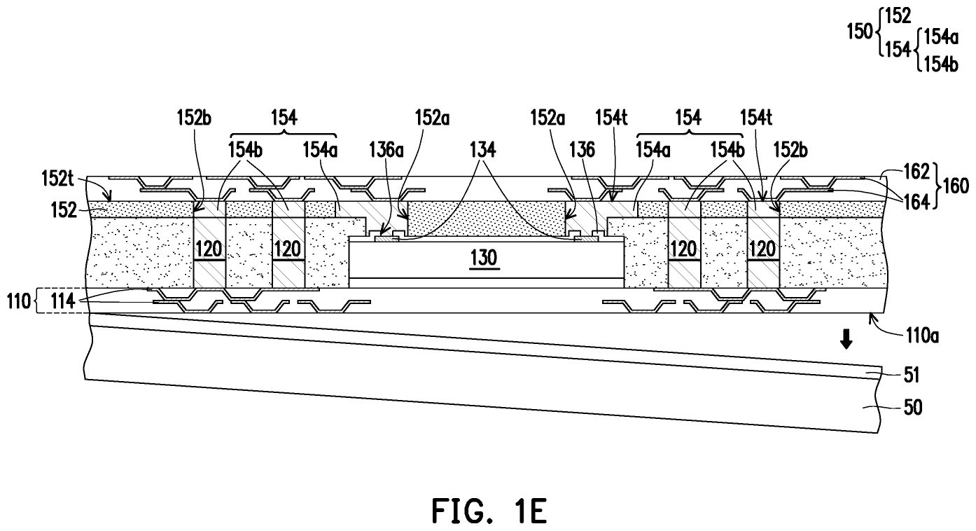

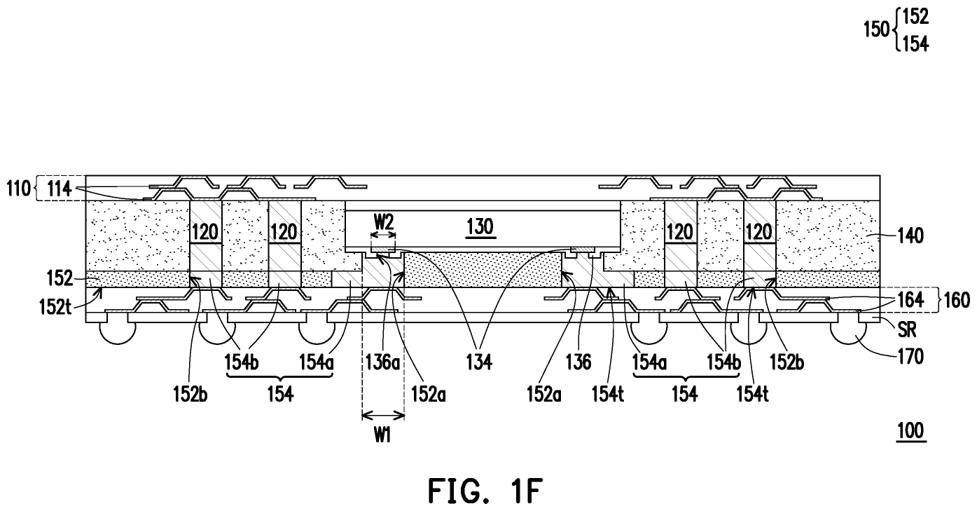

FIG. 1A to FIG. 1F are schematic cross-sectional views illustrating a manufacturing method of a semiconductor package according to an embodiment of the disclosure. Referring to FIG. 1A, a backside redistribution layer (RDL) 110 is formed on a temporary carrier 50. For example, the temporary carrier 50 may be a wafer-level or panel-level substrate made of glass, plastic, metal, or other suitable materials as long as the material is able to withstand the subsequent processes while carrying the structure formed thereon. The backside RDL 110 may include a first surface 110a facing toward the temporary carrier 50, and a second surface 110b opposite to the first surface 110a. In some embodiments, a de-bonding layer 51 may be disposed between the first surface 110a of the backside RDL 110 and the temporary carrier 50 to enhance the releasibility of the backside RDL 110 from the temporary carrier 50 in the subsequent processes. For example, the de-bonding layer 51 includes a light to heat conversion (LTHC) release layer or other suitable release layers. In other embodiments, the de-bonding layer 51 is omitted, and the first surface 110a of the backside RDL 110 may be in direct contact with the temporary carrier 50.

In some embodiments, the backside RDL 110 includes at least one patterned dielectric layer 112 and at least one patterned conductive layer 114 embedded in the patterned dielectric layer 112. The patterned conductive layer 114 of the backside RDL 110 may include lines, pads, vias, etc. In an exemplary embodiment, the formation of the backside RDL 110 includes at least the following steps. A dielectric material may be formed over the temporary carrier 50 using any suitable deposition process such as spin-coating, lamination, or the like. Next, a portion of the dielectric material is removed to form the patterned dielectric layer 112 with openings (not labeled) using such as a lithography (i.e., exposure and development processes) and an etching process, or other suitable removing process. A material of the patterned dielectric layer 112 may include inorganic or organic dielectric materials such as polyimide (PI), polybenzoxazole (PBO), benezocyclobutene (BCB), etc.

Subsequently, the patterned conductive layer 114 is formed to be inlaid with the patterned dielectric layer 112. For example, a seed layer (not illustrated) is conformally formed on the patterned dielectric layer 112 and inside the openings of the patterned dielectric layer 112, and then a patterned photoresist layer (not illustrated) having openings may be formed on the patterned dielectric layer 112. Next, a conductive material layer (e.g., copper, aluminium, nickel, gold, metal alloy, etc.; not illustrated) may be formed on the seed layer and inside the openings of the patterned photoresist layer using plating, sputtering, or other suitable process. Subsequently, the patterned photoresist layer may be removed, and then the seed layer unmasked by the conductive material layer may be removed to form the patterned conductive layer 114. The abovementioned steps may be performed multiple times to obtain a multi-layered RDL as required by the circuit design. At least a portion of the topmost and/or bottommost layers of the patterned conductive layer 114 may be exposed by the patterned dielectric layer 112 for further electrical connection. In some embodiments, the patterned conductive layer 114 is formed prior to the patterned dielectric layer 112. It should be noted that the patterned conductive layer and the patterned dielectric layer illustrated throughout the drawings are only for illustrative purpose and may be adjusted depending on the product requirements.

Referring to FIG. 1B, a conductive connector 120 and a bumpless die 130 disposed side by side are provided on the second surface 110b of the backside RDL 110. In some embodiments, multiple conductive connectors 120 are arranged to surround the bumpless die 130. In some embodiments, a pitch P between two adjacent conductive connectors 120 may range from 180 μm to 300 μm approximately. A width (e.g., diameter) of one of the conductive connectors 120 may be about 200 μm. It should be noted that the pitch and the size of the conductive connectors 120 may be adjusted depending on the product or process requirements. In an exemplary embodiment, the forming process of the conductive connectors 120 includes at least the following steps. After forming the backside RDL 110, a patterned photoresist layer with openings (not illustrated) may be formed on the second surface 110b of the backside RDL 110. For example, the openings of the patterned photoresist layer may expose predetermined locations of the underlying patterned conductive layer 114 for the subsequently formed conductive connectors 120. Next, a conductive material layer is formed on the patterned conductive layer 114 and inside the openings of the patterned photoresist layer using plating or other suitable deposition process. Subsequently, the patterned photoresist layer is removed so that the conductive material layer is remained on the second surface 110b of the backside RDL 110 to form the conductive connectors 120. Alternatively, the conductive connectors 120 are pre-formed and may be disposed on the backside RDL 110 through a pick and place process and a suitable bonding process. In some embodiments, each of the conductive connectors 120 has sidewalls which are substantially perpendicular to the second surface 110b of the backside RDL 110. In other embodiments, the conductive connectors 120 have slanted sidewalls according to the manufacturing process. It should be appreciated that the conductive connectors 120 may be provided in any suitable forms or shapes (e.g., pillars, balls, etc.) depending on the design requirements.

In some embodiments, the bumpless die 130 is disposed on the second surface 110b of the backside RDL 110 after forming the conductive connectors 120. For example, the bumpless die 130 includes a semiconductor substrate 132 having a front surface 132a and a back surface 132b opposite to each other, a plurality of conductive pads 134 disposed on the front surface 132a of the semiconductor substrate 132, and a passivation layer 136 disposed on the semiconductor substrate 132 and partially exposing the conductive pads 134. It should be appreciated that the term “bumpless” refers to the absence of solder bumps or copper bumps on the conductive pads 134 when the die is initially provided. In some embodiments, the bumpless die 130 is provided with a protective layer 138 at least covering the conductive pads 134 for protection. In other embodiments, the protective layer 138 is omitted. It should be noted that the protective layer 138 shown in FIG. 1B is an illustrative example, and the protective layer may be formed as a sporadic pattern which only covers the conductive pads and the overlying portion of the passivation layer 136 as described later in other embodiments.

For example, the bumpless die 130 is singulated from a device wafer (not shown). In some embodiments, the semiconductor substrate 132 includes a variety of active components (e.g., transistors; not shown) and/or passive components (e.g., resistors, capacitors; not shown) formed therein. The conductive pads 134 may be electrically coupled to the active and/or passive components in the semiconductor substrate 132. For example, the conductive pads 134 include aluminum pads, copper pads, or the like. The passivation layer 136 may include openings 136a exposing at least a portion of the conductive pads 134 for electrical connection. A material of the passivation layer 136 includes silicon oxide, silicon nitride, silicon oxynitride, or the like. The protection layer 138 may be disposed on the passivation layer 136 and cover the conductive pads 134 to prevent the conductive pads 134 from damage during processing. Materials of the protection layer 138 and the passivation layer 136 may be similar or different. For example, the protection layer 138 may include polyimide (PI), polybenzoxazole (PBO), benezocyclobutene (BCB), etc. In some embodiments, the bumpless die 130 is provided with a bonding layer DAF adhered to the back surface 132b of the semiconductor substrate 132. The bumpless die 130 may be attached to the backside RDL 110 through the bonding layer DAF. In alternative embodiments, the bumpless die 130 is disposed on the backside RDL 110 before providing the conductive connectors 120. The providing sequence of the conductive connectors 120 and the bumpless die 130 may be adjusted according to the process requirements.

Referring to FIG. 1C, an insulating encapsulation 140 is formed on the second surface 110b of the backside RDL 110 to encapsulate the conductive connectors 120 and the bumpless die 130. The insulating encapsulation 140 may be formed by an insulating material such as epoxy or other suitable resins. In some embodiments, the insulating encapsulation 140 includes a molding compound formed by a molding process. For example, an insulating material is formed on the second surface 110b of the backside RDL 110 such that the bumpless die 130 and the conductive connectors 120 are over-molded. Subsequently, the insulating material is thinned to expose at least a portion of the conductive connectors 120 for further electrical connection, such that the insulating encapsulation 140 is formed. For example, the thinning process includes a grinding process, a chemical-mechanical polishing (CMP) process, an etching process, etc. In some embodiments in which the protection layer 138 does not entirely cover the passivation layer 136, the insulating encapsulation 140 may cover the region of the passivation layer 136 of the bumpless die 130 which is unmasked by the protective layer 138. In some embodiments, the protective layer 138 of the bumpless die 130 is slightly thinned along with the insulating material during the process. A planarization process is optionally performed on the insulating material and/or the conductive connectors 120. In some embodiments, the top surface 140a of the insulating encapsulation 140 is substantially coplanar with the top surfaces 120a of the conductive connectors 120. In certain embodiments in which the insulating encapsulation 140 including a molding compound, the conductive connectors 120 penetrating through the insulating encapsulation 140 may be referred to as the through molding vias (TMVs).

Referring to FIG. 1D, a circuit layer 150 is formed on the bumpless die 130, the conductive connectors 120, and the insulating encapsulation 140. The circuit layer 150 includes a dielectric pattern 152 and a conductive pattern 154 inlaid with the dielectric pattern 152. The conductive pattern 154 may be physically and electrically connected to the conductive connectors 120 and the conductive pads 134 of the bumpless die 130. The conductive pattern 154 may include lines, vias, etc.

In some embodiments, after forming the insulating encapsulation 140, the protection layer 138 of the bumpless die 130 is removed to reveal the conductive pads 134 of the bumpless die 130. Next, the dielectric pattern 152 is formed on the insulating encapsulation 140 and the bumpless die 130 using lithography and etching, lamination, or other suitable process. A material of the dielectric pattern 152 includes polyimide (PI), polybenzoxazole (PBO), benezocyclobutene (BCB), or other suitable insulating materials. A portion of the dielectric pattern 152 may be formed on the top surface 140a of the insulating encapsulation 140. The other portion of the dielectric pattern 152 may be formed on the bumpless die 130. For example, the other portion of the dielectric pattern 152 is formed on the passivation layer 136 and between two adjacent conductive pads 134. In some embodiments, the portion of the dielectric pattern 152 formed on the insulating encapsulation 140 has a thickness thinner than the other portion of the dielectric pattern 152 formed on the bumpless die 130. The dielectric pattern 152 may include a plurality of first openings 152a and a plurality of second openings 152b. The first openings 152a of the dielectric pattern 152 may expose at least the conductive pads 134 and a portion of the passivation layer 136 covering on the conductive pads 134. In some embodiments, one of the first openings 152 may be formed as a continuous recess exposing the conductive pads 134, a portion of the passivation layer 136 covering on the conductive pads 134, and a portion of the insulating encapsulation 140. For example, the first openings 152a may expose at least a portion of the insulating encapsulation 140 disposed between the sidewalls of the bumpless die 130 and the closest ones of the conductive connectors 120. In some embodiments, the size of the first openings 152a is greater than the size of the openings 136a of the passivation layer 136. The second openings 152b of the dielectric pattern 152 may expose at least a portion of the conductive connectors 120. In some embodiments, the first openings 152a and the second openings 152b are not in communication with one another.

Subsequently, a conductive material may be formed in the first openings 152a and the second openings 152b to form the conductive pattern 154 such that the conductive pattern 154 is laterally covered by the dielectric pattern 152. The conductive material may be formed using plating, sputtering, or other suitable deposition process. For example, a portion of the conductive material is formed on the conductive pads 134 and extends to cover the top surface 140a of the insulating encapsulation 140. The conductive pattern 154 includes a plurality of first conductive features 154a disposed in the first openings 152a of the dielectric pattern 152 and connected to the conductive pads 134, and a plurality of second conductive features 154b disposed in the second openings 152b and connected to the conductive connectors 120.

In some embodiments, the pitch between the adjacent second conductive features 154b may be similar to the pitch between the underlying conductive connectors 120. In some embodiments, the first conductive features 154a are disposed on the insulating encapsulation 140 and extend along a thickness direction TD of the bumpless die 130 to be physically connected to the conductive pads 134 of the bumpless die 130. Since the size of the first openings 152a is greater than the openings 136a of the passivation layer 136, the first conductive features 154a formed in the first openings 152a may cover the conductive pads 134 exposed by the openings 136a of the passivation layer 136 and the portion of the passivation layer 136 overlying the conductive pads 134. In some embodiments, the first conductive features 154a further cover a portion of the top surface 140a of the insulating encapsulation 140 located between the conductive connectors 120 and the sidewall of the bumpless die 130. The area of the top surface 140a of the insulating encapsulation 140 covered by the first conductive features 154a may depend on the size of the first openings 152a of the dielectric pattern 152 and may be adjusted. In some embodiments, a sidewall of each first conductive feature 154a is covered by the portion of the dielectric pattern 152 disposed on the passivation layer 136 of the bumpless die 130, and opposing sidewalls of each first conductive feature 154a may be covered by the insulating encapsulation 140 and the other portion of the dielectric pattern 152 disposed on the insulating encapsulation 140.

In some embodiments, a width W1 of the portion of the first conductive features 154a disposed right on the bumpless die 130 and connected to the conductive pads 134 may be greater than a width W2 of the underlying conductive pad 134. The conductive lines of the patterned the backside RDL 110 and the conductive pattern 154 include line width (L) and line spacing (S). In some embodiments, the line/spacing (L/S) routing of the backside RDL 110 is finer than that of the circuit layer 150. For example, the line/spacing routing of the circuit layer 150 may be at least ten times greater than that of the backside RDL 110. After forming the conductive material, a planarization process (e.g., grinding) is optionally performed. In some embodiments, the top surface 152t of the dielectric pattern 152 and the top surface 154t of the conductive pattern 154 are substantially coplanar.

Referring to FIG. 1E, a front side RDL 160 is formed on the circuit layer 150. The front side RDL 160 may include at least one patterned dielectric layer 162 and at least one patterned conductive layer 164 embedded in the patterned dielectric layer 162. In some embodiments, the line and spacing routing of the front side RDL 160 is finer than that of the circuit layer 150. The forming process of the front side RDL 160 may be similar to that of the backside RDL 110. For example, a dielectric material may be formed on the top surface 152t of the dielectric pattern 152 and the top surface 154t of the conductive pattern 154. Next, a portion of the dielectric material is removed to form the patterned dielectric layer 162 with openings (not labeled). The patterned conductive layer 164 may be formed on the patterned dielectric layer 162 and in the openings of the patterned dielectric layer 162 to be connected to the conductive pattern 154 of the circuit layer 150. The abovementioned steps may be performed multiple times to obtain a multi-layered RDL as required by the circuit design. In some embodiments, at least a portion of topmost layer of the patterned conductive layer 164 is exposed by the patterned dielectric layer 162 for further electrical connection. Alternatively, the patterned conductive layer 164 is formed prior to the patterned dielectric layer 162. It should be noted that the patterned conductive layer 164 and the patterned dielectric layer 162 are only for illustrative purpose, the front side RDL 160 may be adjusted depending on the product requirements.

In some embodiments, after forming the front side RDL 160, the temporary carrier 50 is removed so that the first surface 110a of the backside RDL 110 is exposed for further processing. For example, the external energy such as UV laser, visible light or heat, may be applied to the de-bonding layer 51 so that the backside RDL 110 may be separated from the temporary carrier 50.

Referring to FIG. 1F, a plurality of conductive terminals 170 may be formed on the front side RDL 160 opposite to the circuit layer 150. The conductive terminals 170 may be formed by a ball mounting process, an electroless plating process, or any other suitable process. For example, the conductive terminals 170 may include conductive balls, conductive pillars, conductive bumps or a combination thereof. Other possible forms and shapes of the conductive terminals 170 may be utilized according to the design requirement. A soldering process and a reflowing process are optionally performed for enhancement of the adhesion between the conductive terminals 180 and the front side RDL 160. In some embodiments, before forming the conductive terminals 170, a solder resist layer SR having a plurality of openings is formed on the front side RDL 160 using printing, spin-coating, or other suitable deposition process. The solder resist layer SR may keep the patterned conductive layers in the front side RDL 160 from external contamination. The conductive terminals 170 may be formed in the openings of the solder resist layer SR. In some other embodiments, the solder resist layer may be also formed on the backside RDL 110 for protection. Alternatively, other package component(s) may be disposed on the backside RDL 110 and/or the conductive terminals 170 to form an electronic device as will be described later in other embodiments.

Subsequently, a singulation process may be performed and the manufacturing process of a semiconductor package 100 is substantially completed as shown in FIG. 1F. The semiconductor package 100 may be referred to as an integrated fan-out (InFO) package. The semiconductor package 100 includes the first conductive features 154a of the circuit layer 150 physically and electrically connected to the conductive pads 134 of the bumpless die 130 and serving as the pseudo-bumps of the bumpless die 130. The width W1 of the portion of the first conductive features 154a disposed right on the bumpless die 130 is greater than the width W2 of the underlying conductive pad 134 so as to allow greater die-shifting tolerance during subsequent manufacturing processes. For example, during the formation of the insulating encapsulation 140, the bumpless die 130 may be slightly shifted due to thermal stress or warpage issue which may lower the precision of the subsequently formed RDL. By forming the dielectric pattern 152 having wider first openings 152a than the width W2 of the conductive pads 134 on the bumpless die 130 and the insulating encapsulation 140 and then forming the first conductive features 154a of the conductive pattern 154 in the first openings 152a, the negative impact of die-shifting issue may be eliminated.

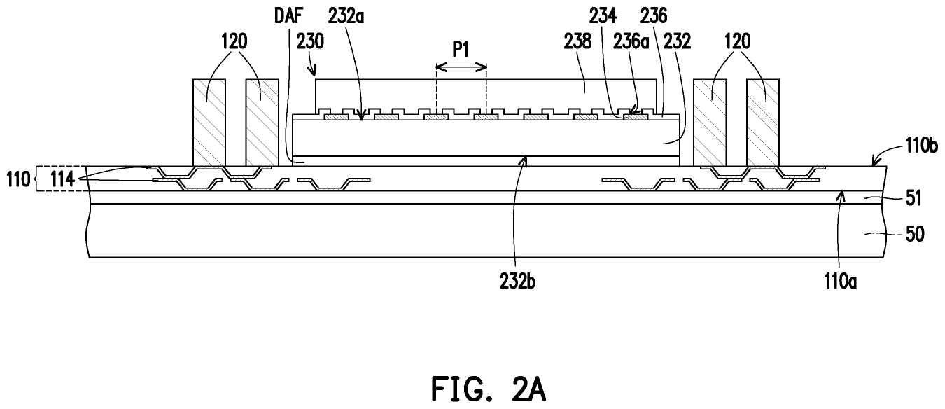

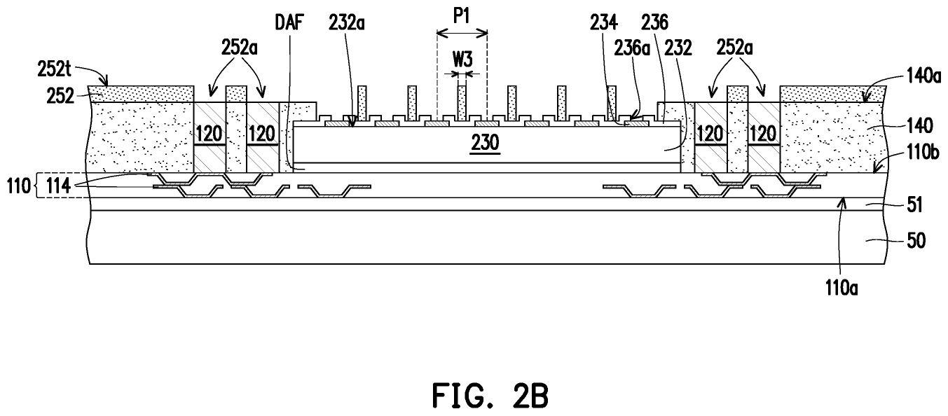

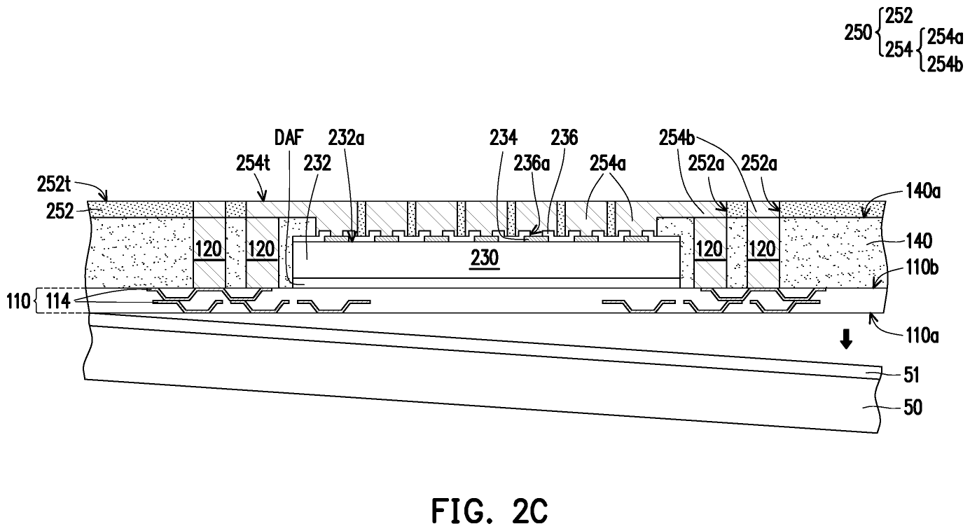

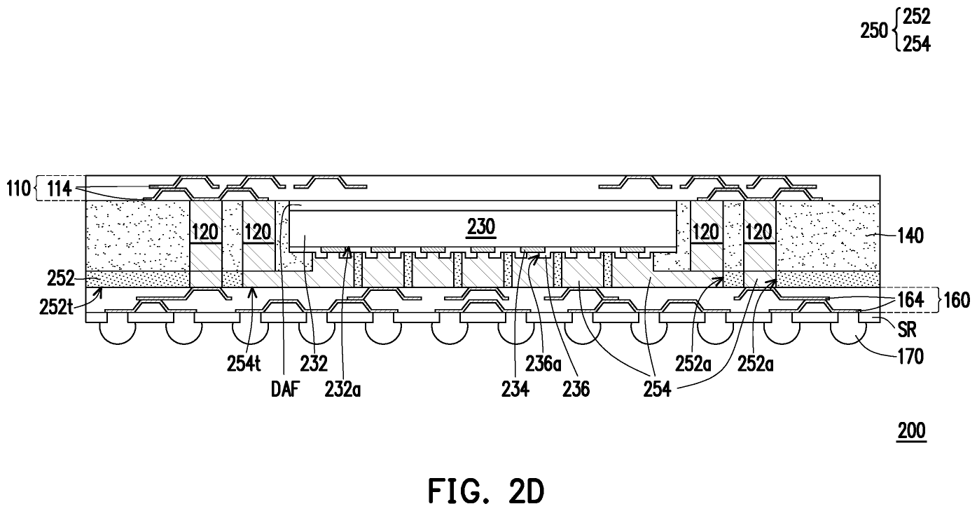

FIG. 2A to FIG. 2D are schematic cross-sectional views illustrating a manufacturing method of a semiconductor package according to an embodiment of the disclosure. For purpose of clarity and simplicity, detail description of same or similar features may be omitted. Herein, identical or similar elements are indicated with the same or similar reference number. Referring to FIG. 2A, a bumpless die 230 and the conductive connectors 120 may be provided on the backside RDL 110. For example, the backside RDL 110 is formed on the temporary carrier 50 with the de-bonding layer 51 interposed therebetween. Next, the conductive connectors 120 may be formed or placed on the second surface 110b of the backside RDL 110 to connect the patterned conductive layer 114 of the backside RDL 110. The bumpless die 230 may be disposed on the backside RDL 110 with the bonding layer DAF bonded to the back surface 232b and the second surface 110b of the backside RDL 110. The providing processes of the conductive connectors 120 and the bumpless die 230 may be adjusted according to process requirements.

In some embodiments, the bumpless die 230 includes a semiconductor substrate 232 having a front surface 232a and the back surface 232b opposite to each other, a plurality of conductive pads 234 disposed on the front surface 232a of the semiconductor substrate 232, and a passivation layer 236 disposed on the semiconductor substrate 232. The passivation layer 236 includes a plurality of openings 236a exposing at least a portion of the conductive pads 234. In some embodiments, the bumpless die 230 is provided with a protective layer 238 at least covering the conductive pads 234 for protection. In other embodiments, the protective layer 238 is omitted. The bumpless die 230 is similar to the bumpless die 130 shown in FIG. 1B, except that the bumpless die 230 including a pitch P1 between two adjacent conductive pads 234 finer than the pitch of two adjacent conductive pads 134 of the bumpless die 130 shown in FIG. 1B.

Referring to FIG. 2B, after providing the bumpless die 230 and the conductive connectors 120, the insulating encapsulation 140 is formed on the backside RDL 110 to at least laterally encapsulate the bumpless die 230 and the conductive connectors 120. The forming process of the insulating encapsulation 140 is similar to the process described in FIG. 1C, so the detailed descriptions are omitted for brevity. In certain embodiments in which the periphery of the passivation layer 236 is unmasked by the protection layer 238, the insulating encapsulation 140 covers the sidewalls of the bumpless die 230 and the insulating encapsulation 140 may laterally extend to cover the periphery of the top surface of the passivation layer 236. After forming the insulating encapsulation 140, the protection layer 238 is removed to expose the conductive pads 234 so that the protection layer 238 is illustrated in FIG. 2B by the dashed line. Subsequently, a dielectric pattern 252 is formed on the passivation layer 236 of the bumpless die 230 and the insulating encapsulation 140. The forming process of the dielectric pattern 252 may be similar to that of the dielectric pattern 152 described in FIG. 1D. In some embodiments, the portions of the dielectric pattern 252 formed on the passivation layer 236 of the bumpless die 230 may be located between the conductive pads 234. For example, in a cross-sectional view as shown in FIG. 2B, a width W3 of each portion of the dielectric pattern 252 formed on the passivation layer 236 is less than the pitch P1 between the conductive pads 234. For example, the width W3 is less than or equal to about 25 μm. In other embodiments in which the conductive pads are arranged to have greater pitches than the present embodiment, the width W3 is greater than about 25 μm.

The dielectric pattern 252 includes a plurality of openings 252a. In some embodiments, the openings 252a expose the conductive pads 234 and/or at least a portion of the conductive connectors 120. In some embodiments, each opening 252a exposes one of the conductive pads 234 and at least a portion of the conductive connectors 120 at the same time. In other embodiments, a group of openings 252a may expose at least a portion of the conductive connectors 120 or at least a portion of the conductive pads 234, and another group of openings 252a may be formed as a plurality of continuous recesses to expose both of a portion of the conductive connectors 120 and the respective conductive pad 234. The size (e.g., width or diameter) of each opening 252a of the dielectric pattern 252 corresponding to the bumpless die 230 may be greater than the size of the corresponding opening 236a of the passivation layer 236. For example, an orthographic projection area of each conductive pad 234 on the second surface 110b of the backside RDL 110 may not overlap an orthographic projection area of the dielectric pattern 252 on the second surface 110b of the backside RDL 110. Some openings 252a of the dielectric pattern 252 may expose the insulating encapsulation 140 disposed between the sidewalls of the bumpless die 230 and the closest ones of the conductive connectors 120. In some embodiments, the insulating encapsulation 140 disposed between the sidewalls of the bumpless die 230 and the closest ones of the conductive connectors 120 may be free of the dielectric pattern 252 formed thereon.

Referring to FIG. 2C, a conductive pattern 254 may be formed in the openings 252a of the dielectric pattern 252 to form a circuit layer 250. The conductive pattern 254 may be physically and electrically connected to the conductive pads 234 of the bumpless die 230 and the conductive connectors 120. For example, a conductive material is formed in the openings 252a of the dielectric pattern 252 using plating, sputtering, or other suitable deposition process. A thinning process and/or a planarization process may be performed to form a planar surface of the circuit layer 250. For example, the top surface 254t of the conductive pattern 254 may be substantially flush with the top surface 252t of the dielectric pattern 252. In some embodiments, a portion of the conductive pattern 254 connected to the conductive pads 234 may be viewed as the first conductive features 254a, and the other portion of the conductive pattern 254 connected to the conductive connectors 120 may be viewed as the second conductive features 254b. In some embodiments, since the first conductive features 254a and the second conductive features 254b are formed at the same time, each of the first conductive features 254a may be connected to one of the second conductive features 254b. In some embodiments, the portion of the conductive pattern 254 in one of the openings 252a of the dielectric pattern 252 is formed in one piece during the same process, and thus, no interface may be present between a portion of the conductive pattern 254 connected to the conductive pads 234 and a corresponding portion of the conductive pattern 254 connected to the conductive connectors 120. Alternatively, some of the first conductive features 254a and the second conductive features 254b may be separated by the dielectric pattern 252. In certain embodiments, since the conductive pattern 254 and the underlying conductive connectors 120 are not formed in the same process (e.g., the conductive connectors 120 may undergo the planarization process), an interface is present between the conductive pattern 254 and the underlying conductive connectors 120.

Referring to FIG. 2D, the front side RDL 160 is formed on the circuit layer 250, and then the conductive terminals 170 is formed on the front side RDL 160. The conductive pads 234 of the bumpless die 230 may face toward the front side RDL 160. The front side RDL 160 is electrically coupled to the bumpless die 230 through the conductive pattern 254 of the circuit layer 250. The solder resist layer SR is optionally formed on the front side RDL 160 to define the locations of the subsequently formed conductive terminals 170. The patterned conductive layer 164 of the front side RDL 160 is electrically connected to the conductive pattern 254 of the circuit layer 250 and the conductive terminals 170 are electrically connected to the patterned conductive layer 164 of the front side RDL 160. Afterwards, a singulation process may be performed to form a semiconductor package 200. The forming processes of the front side RDL 160 and the conductive terminals 170 may be similar to the processes described in FIGS. 1E and 1F, so the detailed descriptions are omitted for brevity. In some embodiments, the semiconductor package 200 includes the conductive pattern 254 of the circuit layer 250 which is simultaneously connected to the conductive pads 234 and the conductive connectors 120 such that the better electrical performance may be achieved.

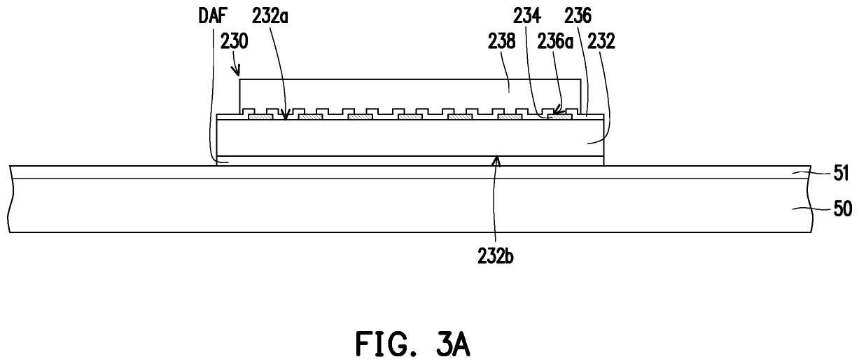

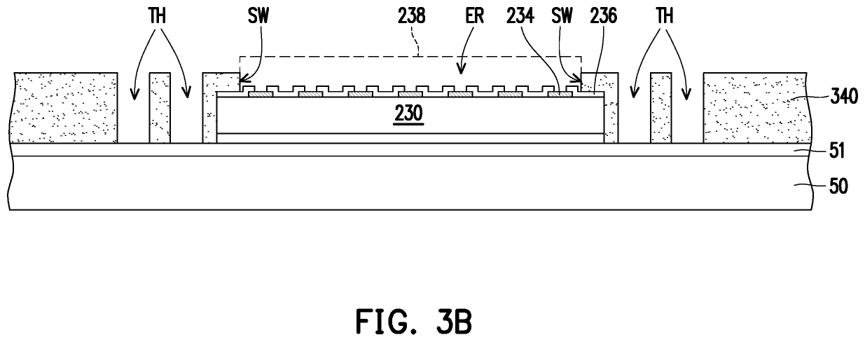

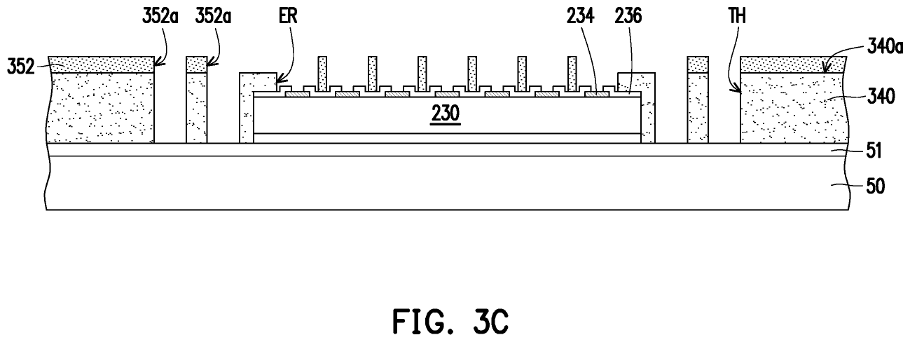

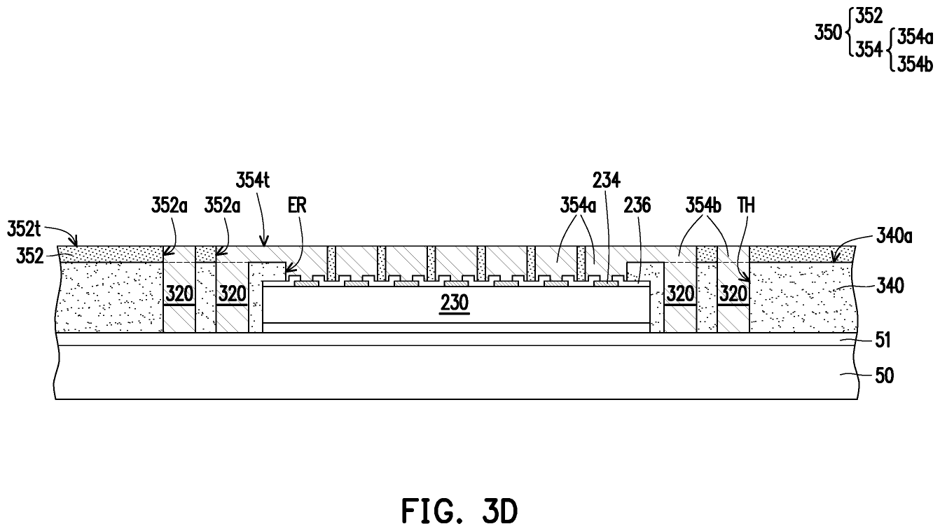

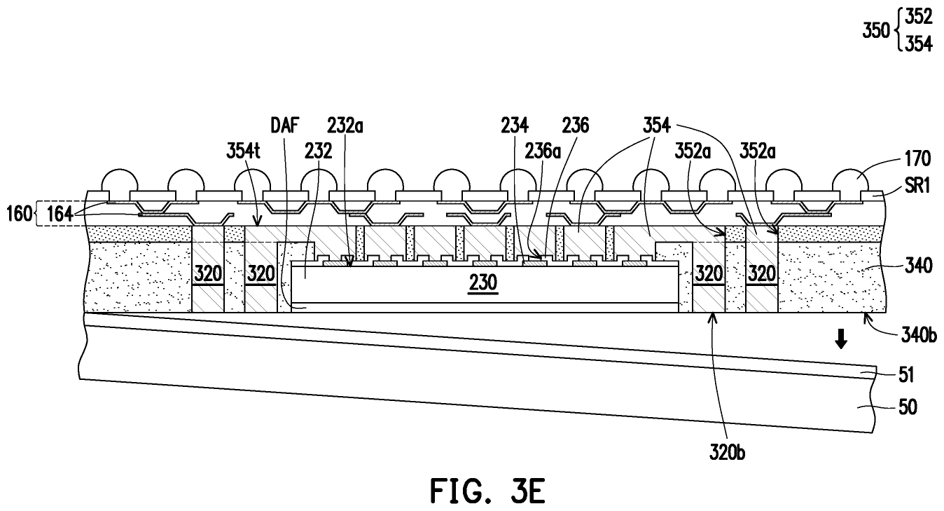

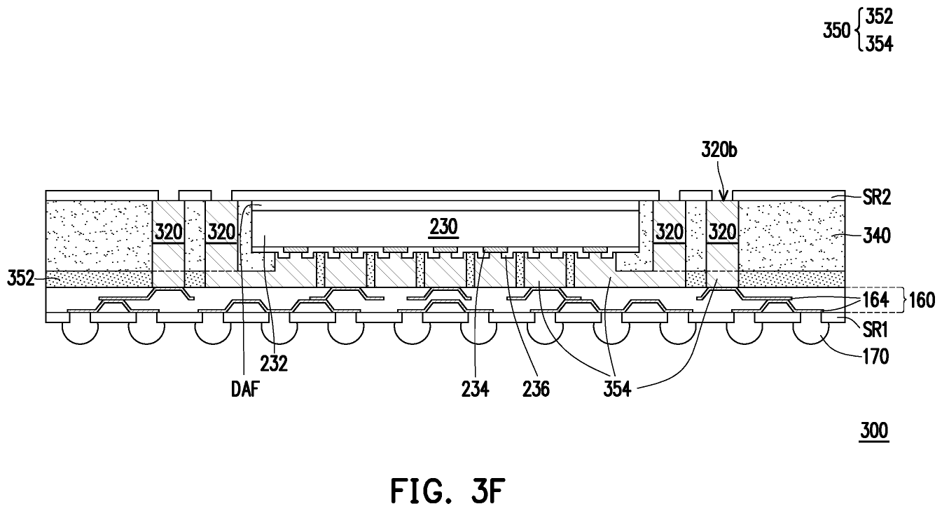

FIG. 3A to FIG. 3F are schematic cross-sectional views illustrating a manufacturing method of a semiconductor package according to an embodiment of the disclosure. For purpose of clarity and simplicity, detail description of same or similar features may be omitted. Herein, identical or similar elements are indicated with the same or similar reference number. Referring to FIG. 3A, the bumpless die 230 is disposed on the temporary carrier 50 using a pick and place process or other suitable techniques. The bumpless die 230 may be singulated from a device wafer (not shown). In some embodiments, the bumpless die 230 is provided with the bonding layer DAF attached onto the back surface 232b of the semiconductor substrate 232. The temporary carrier 50 may be provided with the de-bonding layer 51 formed thereon, and the bonding layer DAF may be in contact with the de-bonding layer 51. Alternatively, the de-bonding layer 51 is omitted. In some embodiments, the bumpless die 230 is provided with the protection layer 238 covering the conductive pads 234. The protection layer 238 may partially cover the passivation layer 236. For example, the periphery of the top surface of the passivation layer 236 is not covered by the protection layer 238. In other embodiments, the entirety of the top surface of the passivation layer 236 is covered by the protection layer 238. Alternatively, the protection layer 238 is omitted.

Referring to FIG. 3B, after disposing the bumpless die 230, an insulating encapsulation 340 is formed over the temporary carrier 50 to at least laterally encapsulate the bumpless die 230. The thickness of the insulating encapsulation 340 may be greater than the thickness of the bumpless die 230. The insulating encapsulation 340 may be formed with a plurality of through holes TH using molding, drilling, grinding, chemical-mechanical polishing, etc. In other embodiments, a sacrificial pattern layer (not shown) may be formed over the temporary carrier 50 at the intended locations for the subsequently formed through holes, and then an insulating material is formed on the temporary carrier 50 to cover the bumpless die 230 and the sacrificial pattern layer. Subsequently, the sacrificial pattern layer is removed so as to form the insulating encapsulation 340 with the through holes TH. For example, the through holes TH are arranged in a predetermined region aside the bumpless die 230 for the subsequently formed conductive connectors.

In certain embodiments in which the bumpless die is provided with the protection layer, after forming the insulating encapsulation 340, the protection layer 238 of the bumpless die 230 is removed to expose the conductive pads 234. In certain embodiments in which the protection layer partially covers the top surface of the passivation layer, as shown in FIG. 3B, the insulating encapsulation 340 covers the sidewalls of the bumpless die 230, and a portion of the insulating encapsulation 340 may extend laterally to cover the periphery of the top surface of the passivation layer 236. The inner sidewalls SW of the insulating encapsulation 340 may define an exposing region ER where the conductive pads 234 are revealed. For example, the exposing region ER is the region initially covered by the protection layer 238. The shape of the exposing region ER may be in compliance with the shape of the protection layer 238.

Referring to FIG. 3C and FIG. 3D, a circuit layer 350 and a plurality of conductive connectors 320 are formed. For example, after forming the insulating encapsulation 340, a dielectric pattern 352 is formed on the top surface 340a of the insulating encapsulation 340. The dielectric pattern 352 includes openings 352a. In some embodiments, at least a portion of the openings 352a may correspond to the through holes TH of the insulating encapsulation 340 so that the through holes TH are in communication with the openings 352a. In some embodiments, at least one of the openings 352a is formed as a continuous recess corresponding to the through holes TH and the exposing region ER at the same time. In some embodiments, a portion of the insulating encapsulation 340 which wraps the sidewalls of the bumpless die 230 and extends to cover the periphery of the top surface of the passivation layer 236 may be exposed by the openings 352a of the dielectric pattern 352. In some embodiments, a portion of the dielectric pattern 352 may be formed on the top surface of the passivation layer 236 and between two adjacent conductive pads 234.

Continue to FIG. 3D, after forming the dielectric pattern 352, a conductive material may be formed in the openings 352a, the though holes TH, and the exposing region ER to form the conductive pattern 354 and the underlying conductive connectors 320 using plating, sputtering, or other suitable deposition process. In some embodiments, the conductive material is over-plated, and then a grinding or planarization process may be performed to remove excess conductive material on the dielectric pattern 352, so that the conductive pattern 354 may be inlaid with the dielectric pattern 352. In some embodiments, the top surface 354t of the conductive pattern 354 and the top surface 352t of the dielectric pattern 352 are substantially coplanar. The portion of the conductive material formed inside the through hole TH of the insulating encapsulation 340 may be viewed as the conductive connectors 320. The other portion of the conductive material formed inside the openings 352a of the dielectric pattern 352 and the exposing region ER may be viewed as the conductive pattern 354. The conductive pattern 354 may include first and second conductive features 354a and 354b connected to one another, which is similar to the conductive pattern 254 described in FIG. 2C. Therefore, the detailed descriptions of the first and second conductive features 354a and 354b are omitted for brevity.

In the present embodiments, the conductive pattern 354 and the conductive connectors 320 are formed during the same process. In some embodiments, since the conductive pattern 354 is continuously connected to the conductive connectors 320, so that no interface may be present between the conductive pattern 354 and the conductive connectors 320. In other embodiments, the conductive pattern 354 and the conductive connectors 320 may be formed by a two-stage deposition process, such that an interface may be formed therebetween. Accordingly, dashed lines illustrated in FIG. 3D indicate that the interface between the conductive pattern 354 and the conductive connectors 320 may be or may not be present.

Referring to FIG. 3E, the front side RDL 160 is formed on the circuit layer 350, the conductive terminals 170 is formed on the front side RDL 160, and the temporary carrier 50 is removed. The patterned conductive layer 164 of the front side RDL 160 is electrically coupled to the bumpless die 230 through the conductive pattern 354 of the circuit layer 350. A first solder resist layer SR1 is optionally formed on the front side RDL 160 to define the locations of the subsequently formed conductive terminals 170. The conductive terminals 170 are electrically coupled to the bumpless die 230 through the patterned conductive layer 164 of the front side RDL 160. The temporary carrier 50 may be de-bonded prior to the forming process of the conductive terminals 170. Alternatively, the temporary carrier 50 may be removed after forming the conductive terminals 170, and then the structure may be flipped upside down for the subsequent process. After removing the temporary carrier 50, the bottom surface 340b of the insulating encapsulation 340, the bottom surface 320b of the conductive connectors 320, and the bonding layer DAF attached to the back surface of the semiconductor substrate 232 of the bumpless die 230 are exposed for further processing.

Referring to FIG. 3F, a second solder resist layer SR2 is optionally formed on the bottom surface 340b of the insulating encapsulation 340, the bottom surface 320b of the conductive connectors 320, and the bonding layer DAF for protection. In some embodiments, the second solder resist layer SR2 includes openings exposing at least a portion of the conductive connectors 320 for further electrical connection. In other embodiments, the second solder resist layer SR2 is omitted. Afterwards, a singulation process is performed to form a semiconductor package 300. The semiconductor package 300 includes the conductive pattern 354 and the conductive connectors 320 formed during the same process, thereby providing better electrical performance. For example, another semiconductor package (not shown) may be stacked on the semiconductor package 300 to be electrically connected to the conductive connectors 320 so as to form a package-on-package (POP) structure. Since the conductive pattern 354 and the conductive connectors 320 are formed as a continuous conductive component, the signal performance transmitting to and from the bumpless die 230 may be improved.

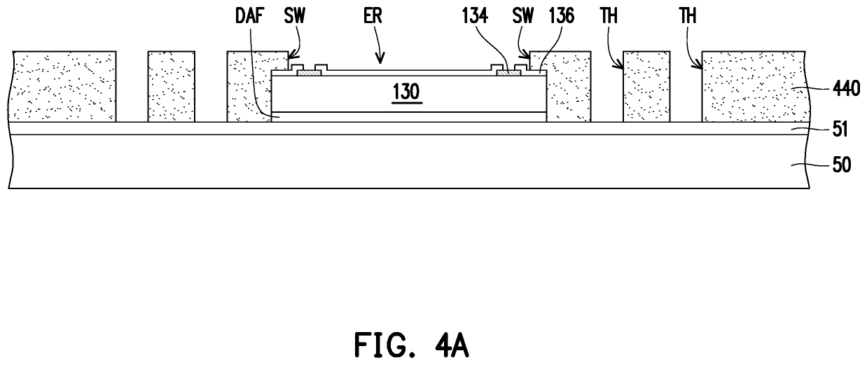

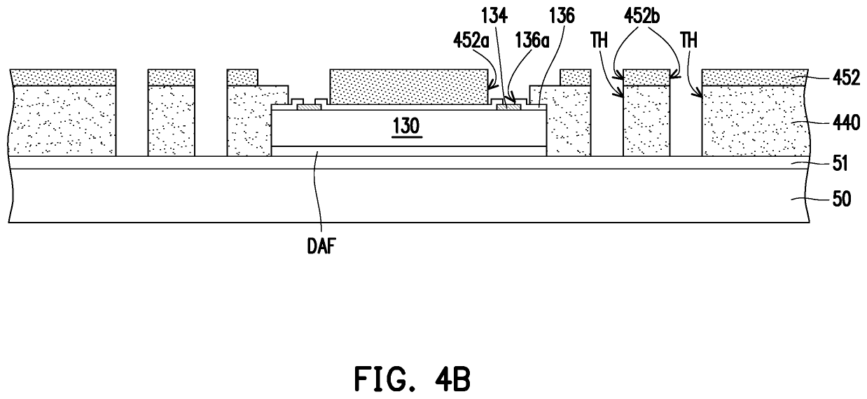

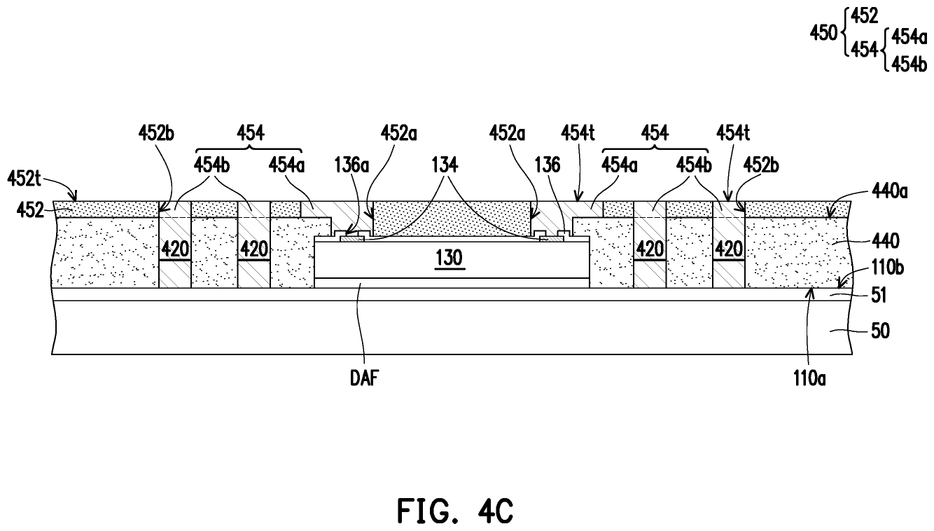

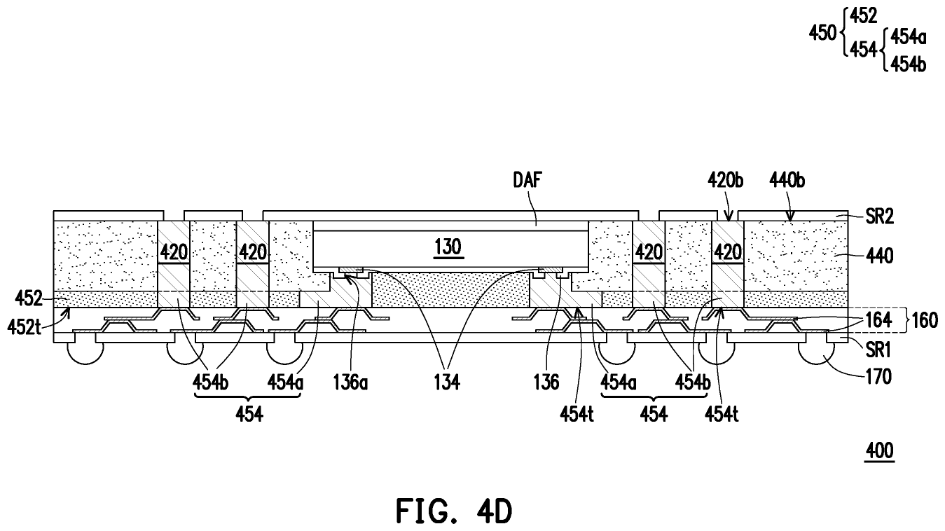

FIG. 4A to FIG. 4D are schematic cross-sectional views illustrating a manufacturing method of a semiconductor package according to an embodiment of the disclosure. For purpose of clarity and simplicity, detail description of same or similar features may be omitted. Herein, identical or similar elements are indicated with the same or similar reference number. Referring to FIG. 4A, the bumpless die 130 is disposed on the temporary carrier 50 and an insulating encapsulation 440 is formed over the temporary carrier 50 to laterally encapsulate the bumpless die 130. The bumpless die 130 may be provided with the bonding layer DAF. The bumpless die 130 may be or may not be provided with a protection layer covering the conductive pads 134. The temporary carrier 50 may be provided with the de-bonding layer 51 formed thereon to enhance the releaseability. The insulating encapsulation 440 includes the through holes TH formed at the intended locations form the subsequently formed conductive connectors. The inner sidewall SW of the insulating encapsulation 440 defines an exposing region ER where the conductive pads 134 are revealed. The forming process of the insulating encapsulation 440 may be similar to that of the insulating encapsulation 340, so the detailed descriptions are omitted for brevity.

Referring to FIG. 4B and FIG. 4C, a circuit layer 450 is formed on the insulating encapsulation 440 and the bumpless die 130. For example, a dielectric pattern 452 including first openings 452a and second openings 452b is formed on the insulating encapsulation 440. In some embodiments, the second openings 452b of the dielectric pattern 452 may correspond to the through holes TH of the insulating encapsulation 440. The first openings 452a of the dielectric pattern 452 may expose the conductive pads 134 revealed by the openings 136a of the passivation layer 136 and the overlying passivation layer 136. Part of the dielectric pattern 452 may be formed on the passivation layer 136 between two adjacent conductive pads 134. The first openings 452a and the second openings 452b may be or may not be in communication with one another.

Subsequently, a conductive material may be formed in the dielectric pattern 452 and the through holes TH of the insulating encapsulation 440 to form the conductive pattern 454 and the underlying conductive connectors 420. In some embodiments, the conductive material is over-plated, and then a grinding or planarization process may be performed to remove excess conductive material on the dielectric pattern 452 so that the top surface 454t of the conductive pattern 454 may be substantially flush with the top surface 452t of the dielectric pattern 452. The portion of the conductive material formed inside the through hole TH of the insulating encapsulation 440 may be viewed as the conductive connectors 420, and the other portion of the conductive material formed inside the first and second openings 452a and 452b of the dielectric pattern 452 may be respectively viewed as the first conductive features 454a of the conductive pattern 454 and the second conductive features 454b of the conductive pattern 454. The first conductive features 454a of the conductive pattern 454 may be physically and electrically connected to the conductive pads 134 of the bumpless die 130. The second conductive features 454b of the conductive pattern 454 and the underlying conductive connectors 420 may be formed as a continuous conductive component.

The first conductive features 454a and the second conductive features 454b may be spatially apart by the dielectric pattern 452. Alternatively, at least one of the first conductive features 454a and the second conductive features 454b may be connected to each other. The second conductive features 454b of the conductive pattern 454 and the underlying conductive connectors 420 may be formed during the same process, so that no interface may be present therebetween. In other embodiments, an interface is formed between the conductive pattern 454 and the underlying conductive connectors 420 due to the different forming processes. Accordingly, the dashed lines illustrated in FIG. 4C indicate that the interface between the second conductive features 454b of the conductive pattern 454 and the conductive connectors 420 may be or may not be present.

Referring to FIG. 4D, the front side RDL 160 is formed on the dielectric pattern 452 and the conductive pattern 454 of the circuit layer 450, and the conductive terminals 170 is formed on the front side RDL 160. The bumpless die 130 may be electrically coupled to the conductive connectors 420 through the conductive pattern 454 and the patterned conductive layer 164 of the front side RDL 160. The patterned conductive layer 164 of the front side RDL 160 may be electrically coupled to the bumpless die 130 through the first conductive features 454a of the conductive pattern 454 of the circuit layer 450. The first solder resist layer SR1 is optionally formed on the front side RDL 160. The conductive terminals 170 are electrically coupled to the bumpless die 130 through the patterned conductive layer 164 of the front side RDL 160. The temporary carrier 50 may be de-bonded prior to the forming process of the conductive terminals 170 or after forming the conductive terminals 170. In some embodiments, after removing the temporary carrier 50, the second solder resist layer SR2 is formed on the bottom surface 440b of the insulating encapsulation 440, the bottom surface 420b of the conductive connectors 420, and the bonding layer DAF. The second resist layer SR may include openings exposing at least a portion of the conductive connectors 420 for further electrical connection. Alternatively, the second solder resist layer SR2 may be replaced by a backside RDL (not shown). Afterwards, a singulation process is performed to form a semiconductor package 400.

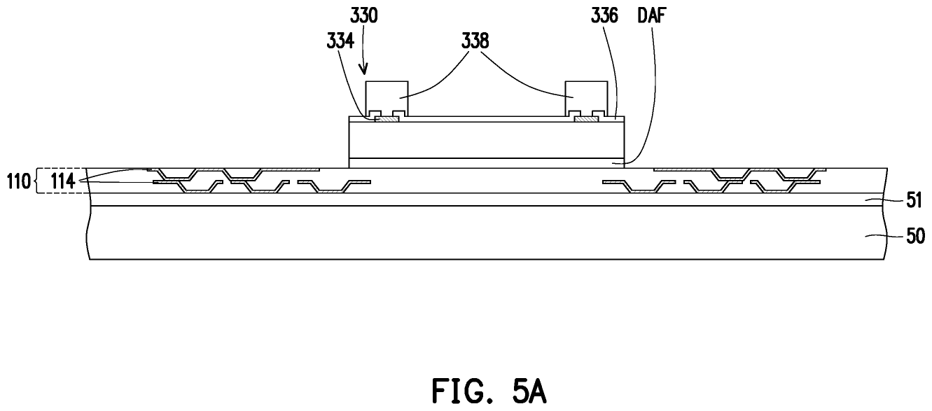

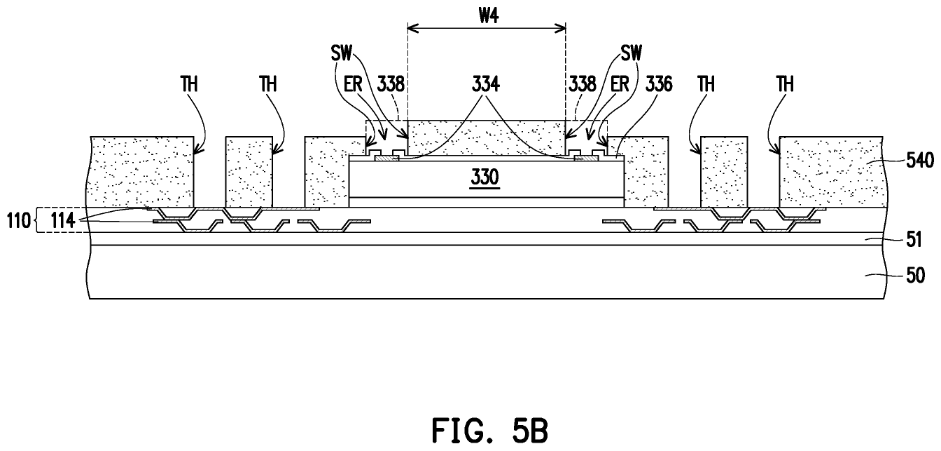

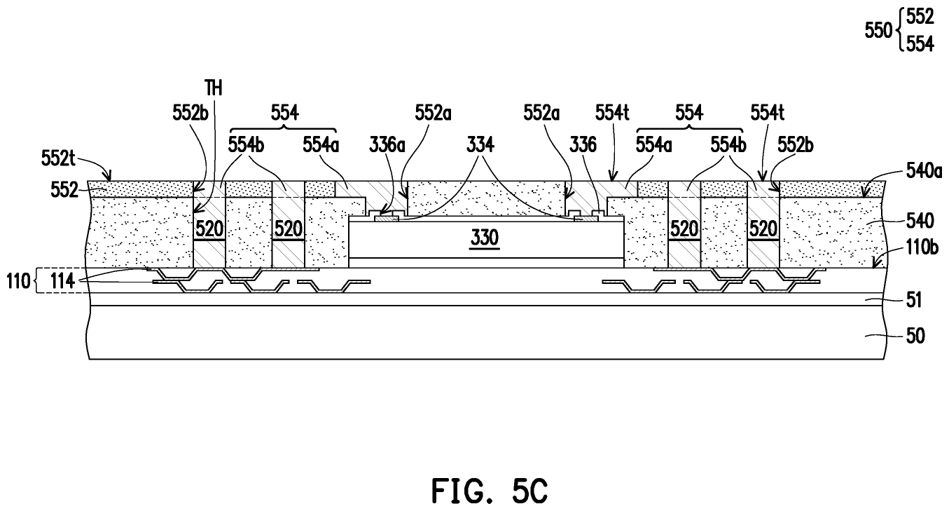

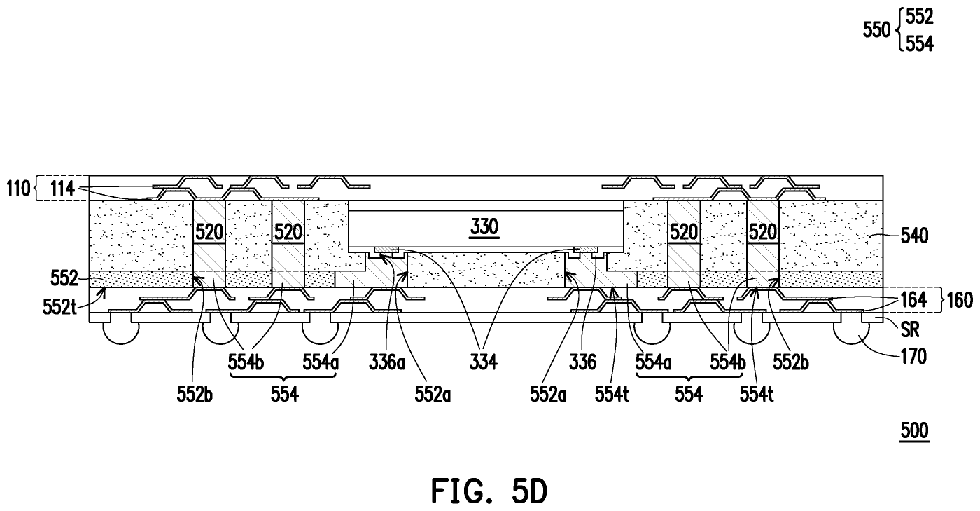

FIG. 5A to FIG. 5D are schematic cross-sectional views illustrating a manufacturing method of a semiconductor package according to an embodiment of the disclosure. For purpose of clarity and simplicity, detail description of same or similar features may be omitted. Herein, identical or similar elements are indicated with the same or similar reference number. Referring to FIG. 5A, the backside RDL 110 is formed over the temporary carrier 50. A bumpless die 330 is disposed on the backside RDL 110. The de-bonding layer 51 may be disposed between the backside RDL 110 and the temporary carrier 50 to enhance the releasibility of the backside RDL 110. The bonding layer DAF may be bonded the bumpless die 330 to the backside RDL 110. Alternatively, the backside RDL 110 is omitted. The bumpless die 330 may be similar to the bumpless die 130 described in FIG. 1B, except that the protection layer 338 may be provided as a sporadic pattern covering a portion of the passivation layer 336 and the underlying conductive pads 334. In some embodiments, the area of the passivation layer 336 unmasked by the protection layer 338 may be greater than the area of the passivation layer 336 covered by the protection layer 338. However, the ratio of the masked and unmasked areas of the passivation layer 336 is not limited in the disclosure.

Referring to FIG. 5B, an insulating encapsulation 540 including a plurality of through holes TH is formed on the backside RDL 110 to cover the bumpless die 330. For example, an insulating material is formed over the backside RDL 110 and the bumpless die 330 may be over-molded by the insulating material. Next, a portion of the insulating material is removed to form the insulating encapsulation 540 with the through holes TH. Subsequently, the protection layer 338 is removed so that the protection layer 338 in FIG. 5B is illustrated by the dashed lines. Since the protection layer 338 is provided as the sporadic pattern, a portion of the insulating encapsulation 540 may be formed on the passivation layer 336 between the conductive pads 334. In some embodiments, the portion of the insulating encapsulation 540 formed on the bumpless die 330 has a width W4. For example, the width W4 is greater than about 25 μm. After removing the protection layer 338, the conductive pads 334 are revealed. The inner sidewalls SW of the insulating encapsulation 540 defines an exposing region ER where the conductive pads 334 are revealed. The exposing region ER may be the region where the protection layer 338 is located, such that the shape of the exposing region ER may be in compliance with the shape of the protection layer 338.

Referring to FIG. 5C, a circuit layer 550 and conductive connectors 520 are formed on the insulating encapsulation 540 and the bumpless die 330. The circuit layer 550 includes a dielectric pattern 552 and a conductive pattern 554. In some embodiments, the top surface 552t of the dielectric pattern 552 and the top surface 554t of the conductive pattern 554. The dielectric pattern 552 includes openings 552a which may correspond to the through holes TH of the insulating encapsulation 540. In some embodiments, the area above the bumpless die 330 is free of the dielectric pattern 552. For example, an orthographic projection area of the dielectric pattern 552 on the second surface 110b of the backside RDL 110 may not overlap an orthographic projection area of the bumpless die 330 on the second surface 110b of the backside RDL 110. The conductive connectors 520 and the conductive pattern 554 of the circuit layer 550 may be formed during the same process. The portion of the conductive material formed inside the through hole TH of the insulating encapsulation 540 may be viewed as the conductive connectors 520. The other portion of the conductive material formed inside the openings 552a of the dielectric pattern 552 and the exposing region ER may be viewed as the conductive pattern 554. The conductive pattern 554 includes the first conductive features 554a and the second conductive features 554b. The first conductive features 554a formed in the exposing region ER are physically and electrically connected to the conductive pads 334 of the bumpless die 330. The second conductive features 554b formed in the openings 552a of the dielectric pattern 552 may be formed together with the conductive connectors 520. The dielectric pattern 552, a portion of the insulating encapsulation 540 formed on the bumpless die 330, and another portion of the insulating encapsulation 540 formed between the bumpless die 330 and the conductive connectors 520 may cover the sidewalls of the first conductive features 554a.

Referring to FIG. 5D, the front side RDL 160 is formed on the dielectric pattern 552 and the conductive pattern 554 of the circuit layer 550, and the conductive terminals 170 is formed on the front side RDL 160. The bumpless die 330 may be electrically coupled to the conductive connectors 520 through the first and second conductive features 554a and 554b of the conductive pattern 554 and the patterned conductive layer 164 of the front side RDL 160. The patterned conductive layer 164 of the front side RDL 160 is electrically coupled to the bumpless die 330 through the first conductive features 554a of the conductive pattern 554 of the circuit layer 550. The first solder resist layer SR1 is optionally formed on the front side RDL 160. The conductive terminals 170 are electrically coupled to the bumpless die 330 through the patterned conductive layer 164 of the front side RDL 160. The temporary carrier 50 may be de-bonded prior to the forming process of the conductive terminals 170 or after forming the conductive terminals 170. Afterwards, a singulation process is performed to form a semiconductor package 500.

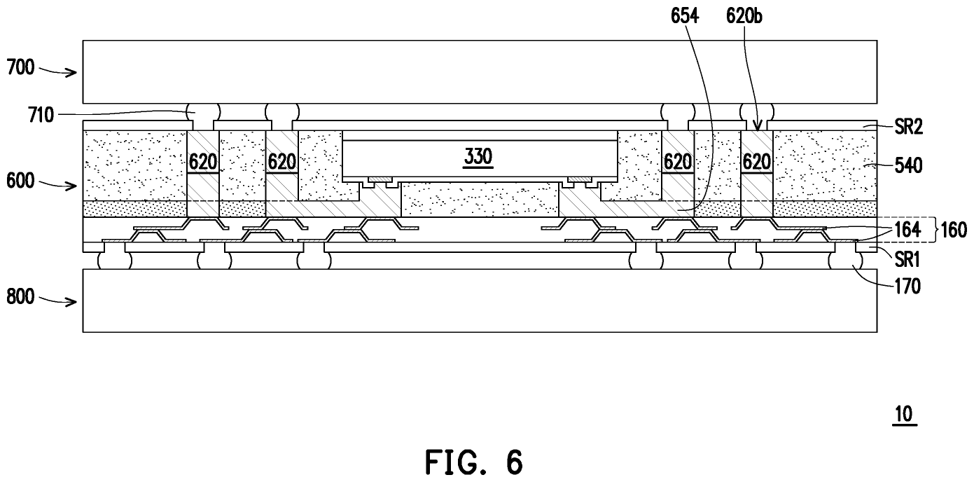

FIG. 6 is a schematic cross-sectional view illustrating an application of a semiconductor package according to an embodiment of the disclosure. For purpose of clarity and simplicity, detail description of same or similar features may be omitted. Herein, identical or similar elements are indicated with the same or similar reference number. Referring to FIG. 6, an electronic device 10 including the semiconductor package 600 is provided. The semiconductor package 600 may be similar to the semiconductor package 500 shown in FIG. 5D, except that the backside RDL is replaced by the second solder resist layer SR2 and at least a portion of the conductive pattern 654 and the conductive connectors 620 are formed integrally. The forming process of the conductive pattern 654 and the conductive connectors 620 may be similar to the process described in FIG. 2C, so the detailed descriptions are not repeated herein. The second solder resist layer SR2 may include a plurality of openings exposing at least a portion of the bottom surface 620b of the conductive connectors 620.

In some embodiments, a first package component 700 is stacked on the semiconductor package 600. For example, the first package component 700 including external terminals 710 is disposed on the solder resist layer SR2. In some embodiments, the external terminals 710 include solder balls which may be reflowed to connect the conductive connectors 620. The semiconductor package 600 is optionally mounted onto a second package component 800. In certain embodiments in which the conductive terminals 170 including solder balls, the conductive terminals 170 of the semiconductor package 600 may be reflowed to be connected to the contact pads (not shown) of the second package component 800. In some embodiments, the first package component 700 and/or the second package component 800 may be or may include another semiconductor package operating the same or different function(s) with respect to the semiconductor package 600. The first package component 700 and the second package component 800 may include a package substrate, an electronic circuit board, a motherboard, a system board, etc. More or less package component(s) may be mounted onto the semiconductor package 600 depending on the product requirements. It should be noted that the semiconductor package 600 may be replaced by the semiconductor package described above so as to open the possibility to various product designs.

Based on the above, since the semiconductor package includes the conductive pattern of the circuit layer which may serve as pseudo-bump to connect the conductive pads of the bumpless die and also reroute the electrical signal of the bumpless die to expand wider than the size of the bumpless die. The conductive pattern may also be connected to the conductive connectors such that the better electrical performance may be achieved while maintaining the process simplicity. The width of the portion of the first conductive features of the conductive pattern disposed right on the respective conductive pad is greater than the width of the underlying conductive pad so as to allow greater die-shifting tolerance during subsequent manufacturing processes.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

1. A semiconductor package, comprising:
a bumpless die, comprising a plurality of conductive pads;
a conductive connector, disposed aside the bumpless die and electrically coupled to the bumpless die;
an insulating encapsulation, encapsulating the bumpless die and the conductive connector;
a circuit layer, electrically connected to the bumpless die and the conductive connector, the circuit layer comprising:
a conductive pattern, disposed on the insulating encapsulation and extending along a thickness direction of the bumpless die to be connected to the conductive pads of the bumpless die; and
a dielectric pattern, disposed on the insulating encapsulation and laterally covering the conductive pattern; and
a front side redistribution layer, disposed on the circuit layer, the front side redistribution layer comprising a finer line and spacing routing than the circuit layer.

2. The semiconductor package of claim 1, wherein the dielectric pattern of the circuit layer is interposed between the insulating encapsulation and the front side redistribution layer, and the conductive pattern of the circuit layer is inlaid with the dielectric pattern.

3. The semiconductor package of claim 1, wherein a surface of the conductive pattern connected to the front side redistribution layer is substantially coplanar with a surface of the dielectric pattern.

4. The semiconductor package of claim 1, wherein a portion of the dielectric pattern is disposed between the two adjacent conductive pads of the bumpless die, and the portion of the dielectric pattern is connected to a sidewall of the conductive pattern.

5. The semiconductor package of claim 1, wherein a portion of the insulating encapsulation is disposed between the two adjacent conductive pads of the bumpless die, and a sidewall of the conductive pattern is connected to the portion of the insulating encapsulation.

6. The semiconductor package of claim 1, wherein the conductive pattern of the circuit layer comprises a first conductive feature disposed on the bumpless die and connected to the conductive pads, and a width of the first conductive feature is greater than a width of the corresponding conductive pad beneath the first conductive feature.

7. The semiconductor package of claim 6, wherein the conductive pattern of the circuit layer further comprises a second conductive feature spatially apart from the first conductive feature by the dielectric pattern, and the second conductive feature is connected to the conductive connector.

8. The semiconductor package of claim 6, wherein the conductive pattern of the circuit layer further comprises a second conductive feature connected to the first conductive feature.

9. The semiconductor package of claim 1, further comprising:
a backside redistribution layer, disposed on the insulating encapsulation opposite to the circuit layer, and electrically connected to the conductive connector, wherein the backside redistribution layer comprises a finer line and spacing routing than the circuit layer.

10. The semiconductor package of claim 1, wherein the insulating encapsulation covers a sidewall of the bumpless die and extend to cover a periphery of a surface of the bumpless die connected to the sidewall.

11. A manufacturing method of a semiconductor package, comprising:
forming an insulating encapsulation to encapsulate a bumpless die and a conductive connector, wherein the bumpless die comprises a plurality of conductive pads unmasked by the insulating encapsulation;
forming a dielectric pattern on the insulating encapsulation, wherein the dielectric pattern comprises a plurality of openings exposing the conductive pads of the bumpless die and at least a portion of the conductive connector;
forming a conductive material in the openings of the dielectric pattern to form a conductive pattern, wherein the conductive pattern is formed on the conductive pads of the bumpless die and laterally extend to cover the insulating encapsulation; and
forming a front side redistribution layer on the dielectric pattern and the conductive pattern, wherein the front side redistribution layer is electrically coupled to the bumpless die through the conductive pattern.

12. The manufacturing method of claim 11, wherein one of the openings of the dielectric pattern is formed as a continuous recess to expose one of the conductive pads of the bumpless die and a portion of the insulating encapsulation connected to the bumpless die.

13. The manufacturing method of claim 11, wherein forming the insulating encapsulation to encapsulate the bumpless die and the conductive connector comprises:
providing the bumpless die and the conductive connector disposed side by side, wherein the bumpless die is provided with a protection layer at least covering the conductive pads; and
forming an insulating material to cover the bumpless die and the conductive connector, and then removing the protective layer to expose the conductive pads of the bumpless die.

14. The manufacturing method of claim 11, wherein forming the insulating encapsulation to encapsulate the bumpless die and the conductive connector comprises:
providing the bumpless die with a protective layer at least covering the conductive pads of the bumpless die;
forming the insulating encapsulation with a through hole to cover at least sidewalls of the bumpless die;
removing the protective layer to expose the conductive pads of the bumpless die; and
forming a conductive material in the through hole of the insulating encapsulation to form the conductive connector aside the bumpless die.

15. The manufacturing method of claim 14, wherein forming the insulating encapsulation with the through hole comprises:
covering the bumpless die with an insulating material; and
removing a portion of the insulating material by drilling to form the through hole.

16. The manufacturing method of claim 14, wherein the protection layer is provided as a sporadic pattern so that after the insulating encapsulation is formed, a portion of the insulating encapsulation is formed on the bumpless die between the two adjacent conductive pads.

17. The manufacturing method of claim 11, wherein the conductive connector and the conductive pattern are formed during the same process.

18. The manufacturing method of claim 17, wherein after forming the insulating encapsulation with a through hole, the dielectric pattern is formed on the insulating encapsulation and one of the openings of the dielectric pattern corresponds to the through hole, and then the conductive connector is formed in the through hole of the insulating encapsulation and the one of the openings of the dielectric pattern.

19. The manufacturing method of claim 11, further comprising:
forming a backside redistribution layer before encapsulating the bumpless die and the conductive connector with the insulating encapsulation, wherein after forming the backside redistribution layer, the bumpless die and the conductive connector are provided on the backside redistribution layer.

20. The manufacturing method of claim 11, further comprising:
before forming the front side redistribution layer, performing a planarization process to the conductive material and the dielectric pattern.
